(19) United States
(12) Patent Application Publication
(10) Pub. No.: US 2013/0327369 A1
(43) Pub. Date: Dec. 12, 2013

(54) THERMOELECTRIC SYSTEM WITH MECHANICALLY COMPLIANT ELEMENT

(71) Applicant: Gentherm Incorporated, Northville, MI (US)

(72) Inventors: Vladimir Jovoic, Pasadena, CA (US); Eric Poliquin, Arcadia, CA (US)

(21) Appl. No.: 13/912,007

(22) Filed: Jun. 6, 2013

Related U.S. Application Data
(60) Provisional application No. 61/656,891, filed on Jun. 7, 2012.
(60) Provisional application No. 61/656,918, filed on Jun. 7, 2012.

(51) Int. Cl. H01L 35/32; H01L 35/34

(52) U.S. Cl. CPC H01L 35/32; H01L 35/34
USPC 136/205; 438/55

(57) ABSTRACT

A thermoelectric system includes at least one first heat exchanger configured to be in thermal communication with a heat source, at least one second heat exchanger configured to be in thermal communication with a heat sink, and at least one thermoelectric assembly including a plurality of thermoelectric elements sealed within an environment including a gas. The at least one thermoelectric assembly is mechanically coupled to the at least one first heat exchanger and mechanically coupled to the at least one second heat exchanger. The at least one thermoelectric assembly is sandwiched between the at least one first heat exchanger and the at least one second heat exchanger. The at least one second heat exchanger includes at least one mechanically compliant element configured to flex in response to at least one dimensional change of the at least one thermoelectric assembly due to thermal expansion or contraction.

### CROSS-REFERENCE TO RELATED APPLICATIONS

This application claims the benefit of priority to U.S. Provisional Appl. No. 61/656,891, filed on Jun. 7, 2012, and U.S. Provisional Appl. No. 61/656,918, filed on Jun. 7, 2012, both of which are incorporated in their entireties by reference herein.

### BACKGROUND

1. Field of the Application

The present application relates generally to thermoelectric cooling, heating, and power generation systems.

2. Description of the Related Art

Thermoelectric (TE) devices and systems can be operated in either heating/cooling or power generation modes. In the former, electric current is passed through a TE device to pump the heat from the cold side to the hot side. In the latter, a heat flux driven by a temperature gradient across a TE device is converted into electricity. In both modalities, the performance of the TE device is largely determined by the figure of merit of the TE material and by the parasitic (dissipative) losses throughout the system. Working elements in the TE device are p-type and n-type semiconducting materials. Mechanical properties of these materials can be brittle with a common mode of failure of TE devices being cracking of the elements caused by the shear loads on the elements.

### SUMMARY

Certain embodiments described herein provide a thermoelectric system comprising at least one first heat exchanger configured to be in thermal communication with a heat source, at least one second heat exchanger configured to be in thermal communication with a heat sink, and at least one thermoelectric assembly comprising a plurality of thermoelectric elements sealed within an environment comprising a gas. The at least one thermoelectric assembly is mechanically coupled to the at least one first heat exchanger and mechanically coupled to the at least one second heat exchanger. The at least one thermoelectric assembly is sandwiched between the at least one first heat exchanger and the at least one second heat exchanger. The at least one second heat exchanger comprises at least one mechanically compliant element configured to flex in response to at least one dimensional change of the at least one thermoelectric assembly due to thermal expansion or contraction.

In certain embodiments, the at least one mechanically compliant element comprises at least one membrane. At least a portion of the at least one membrane is configured to flex in response to the at least one dimensional change of the at least one thermoelectric assembly. The portion of the at least one membrane can be configured to stretch in a direction perpendicular to a direction of heat flow from the at least one first heat exchanger to the at least one second heat exchanger. The at least one membrane can be in contact with a working fluid. The at least one membrane can comprise a gas-impermeable barrier between the environment and the second working fluid. The at least one membrane can comprise regions between at least some adjacent thermoelectric elements of the plurality of thermoelectric elements, with the regions configured to flex in response to the at least one dimensional change of the at least one thermoelectric assembly.

The thermoelectric system can further comprise a plurality of springs mechanically coupled to the at least one membrane and configured to apply a restoring force to the at least one membrane in response to the at least one dimensional change of the at least one thermoelectric assembly. The plurality of springs can comprise a plurality of fins of the at least one second heat exchanger.

In certain embodiments, the at least one first heat exchanger can comprise a first fluid conduit and the at least one second heat exchanger can comprise a plurality of second fluid conduits substantially surrounding the at least one first heat exchanger. The plurality of thermoelectric elements is sandwiched between the first fluid conduit and the plurality of second fluid conduits. Each mechanically compliant element of the at least one mechanically compliant element can be mechanically coupled to a pair of adjacent second fluid conduits of the plurality of second fluid conduits. In certain embodiments, each second fluid conduit of the plurality of second fluid conduits can comprise a flat surface, the first fluid conduit can comprise a plurality of flat surfaces, and the plurality of thermoelectric elements can comprise sets of thermoelectric elements. Each set of thermoelectric elements of the plurality of thermoelectric elements is sandwiched between and in thermal communication with the flat surface of a corresponding second fluid conduit and a corresponding flat surface of the first fluid conduit.

The at least one second heat exchanger can be configured to expand in a radial direction relative to the first fluid conduit by flexing the at least one mechanically compliant element in response to thermal expansion of the plurality of thermoelectric elements.

Certain embodiments described herein provide a method of fabricating a thermoelectric system. The method comprises mechanically coupling at least one first heat exchanger to a plurality of thermoelectric elements. The at least one first heat exchanger is configured to be in thermal communication with a heat source. The method further comprises mechanically coupling at least one second heat exchanger to the plurality of thermoelectric elements. The at least one second heat exchanger is configured to be in thermal communication with a heat sink. The plurality of thermoelectric elements is sandwiched between the at least one first heat exchanger and the at least one second heat exchanger. The at least one second heat exchanger comprises at least one mechanically compliant element configured to flex in response to at least one dimensional change of the thermoelectric system due to thermal expansion or contraction. The method further comprises sealing the plurality of thermoelectric elements within an environment comprising a gas.

The paragraphs above recite various features and configurations of one or more of a thermoelectric assembly, a thermoelectric module, or a thermoelectric system, that have been contemplated by the inventors. It is to be understood that the inventors have also contemplated thermoelectric assemblies, thermoelectric modules, and thermoelectric systems which comprise combinations of these features and configurations from the above paragraphs, as well as thermoelectric assemblies, thermoelectric modules, and thermoelectric systems which comprise combinations of these features and configurations from the above paragraphs with other features and configurations disclosed in the following paragraphs.

### BRIEF DESCRIPTION OF THE DRAWINGS

Various configurations are depicted in the accompanying drawings for illustrative purposes, and should in no way be interpreted as limiting the scope of the thermoelectric assemblies, modules, or systems described herein. In addition, various features of different disclosed configurations can be combined with one another to form additional configurations, which are part of this disclosure. Any feature or structure can be removed, altered, or omitted. Throughout the drawings, reference numbers may be reused to indicate correspondence between reference elements.

FIG. 1 schematically illustrates an example conventional TE device as used for power generation in which heat flux passes from one side to another.

FIG. 2 schematically illustrates an example conventional TE device with encapsulation of the TE elements.

FIG. 3 schematically illustrates an example thermoelectric module in accordance with certain embodiments described herein.

FIGS. 4A-4E schematically illustrates an example thermoelectric module in various stages of fabrication and which is compatible for use in a thermoelectric system in accordance with certain embodiments described herein.

FIG. 5 schematically illustrates a first plurality of shunts comprising conductive integral portions of the at least one heat exchanger in accordance with certain embodiments described herein.

FIGS. 6A and 6B shows the results of a finite-element-analysis (FEA) calculation of the shear stress on thermoelectric elements in a configuration similar to one shown in FIGS. 4A-4E.

FIG. 7 schematically illustrates a cross-sectional view of another example thermoelectric module comprising at least one mechanically compliant element in accordance with certain embodiments described herein.

FIG. 8 schematically illustrates the thermoelectric module of FIGS. 4A-4E with a cooling block housing enclosing the second plurality of fins in accordance with certain embodiments described herein.

FIG. 9 schematically illustrates a cross-sectional view of a thermoelectric module comprising a second plurality of fins coupled to the membrane and in contact with the cooling block housing in accordance with certain embodiments described herein.

FIG. 10 schematically illustrates an example thermoelectric system comprising a plurality of thermoelectric modules in accordance with certain embodiments described herein.

FIG. 11 schematically illustrates another example thermoelectric system comprising a plurality of thermoelectric modules in accordance with certain embodiments described herein.

FIG. 12 schematically illustrates another example thermoelectric system comprising a plurality of thermoelectric modules in accordance with certain embodiments described herein.

FIG. 13 schematically illustrates another example thermoelectric assembly in accordance with certain embodiments described herein.

FIG. 14A schematically illustrates a perspective view of a portion of the example thermoelectric assembly of FIG. 13 in accordance with certain embodiments described herein.

FIG. 14B schematically illustrates a cross-sectional view of thermoelectric system comprising a plurality of the example thermoelectric assemblies of FIG. 13 in accordance with certain embodiments described herein.

FIG. 15 schematically illustrates an example array of thermoelectric systems 200 each comprising a plurality of thermoelectric assemblies 202 in accordance with certain embodiments described herein.

### DETAILED DESCRIPTION

Although certain configurations and examples are disclosed herein, the subject matter extends beyond the examples in the specifically disclosed configurations to other alternative configurations and/or uses, and to modifications and equivalents thereof. Thus, the scope of the claims appended hereto is not limited by any of the particular configurations described below. For example, in any method or process disclosed herein, the acts or operations of the method or process may be performed in any suitable sequence and are not necessarily limited to any particular disclosed sequence. Various operations may be described as multiple discrete operations in turn, in a manner that may be helpful in understanding certain configurations; however, the order of description should not be construed to imply that these operations are order dependent. Additionally, the structures, systems, modules, assemblies, and/or devices described herein may be embodied as integrated components or as separate components. For purposes of comparing various configurations, certain aspects and advantages of these configurations are described. Not necessarily all such aspects or advantages are achieved by any particular configuration. Thus, for example, various configurations may be carried out in a manner that achieves or optimizes one advantage or group of advantages as taught herein without necessarily achieving other aspects or advantages as may also be taught or suggested herein.

A thermoelectric system as described herein can be a thermoelectric generator (TEG) which uses the temperature difference between a heat source and a heat sink to produce electrical power via thermoelectric materials. Alternatively, a thermoelectric system as described herein can be a heater, cooler, or both which serves as a solid state heat pump used to move heat from one surface to another, thereby creating a temperature difference between the two surfaces via the thermoelectric materials. Each of the surfaces can be in thermal communication with a solid, a liquid, a gas, or a combination of two or more of a solid, a liquid, and a gas, and the two surfaces can both be in thermal communication with a solid, both be in thermal communication with a liquid, both be in thermal communication with a gas, or one can be in thermal communication with a material selected from a solid, a liquid, and a gas, and the other can be in thermal communication with a material selected from the other two of a solid, a liquid, and a gas.

The thermoelectric system can include a single thermoelectric assembly (e.g., a single thermoelectric module) or a group of thermoelectric assemblies (e.g., a group of thermoelectric modules), depending on usage, power output, heating/cooling capacity, coefficient of performance (COP) or voltage. Although the examples described herein may be described in connection with either a power generator or a heating/cooling system, the described features can be utilized with either a power generator or a heating/cooling system.

As used herein, the terms “shunt” and “heat exchanger” have their broadest reasonable interpretation, including but not limited to a component (e.g., a thermally conductive device or material) that allows heat to flow from one portion of the component to another portion of the component. Shunts can be in thermal communication with one or more thermoelectric materials (e.g., one or more thermoelectric elements) and in thermal communication with one or more heat exchangers of the thermoelectric assembly, module, or system. Shunts described herein can also be electrically conductive and in electrical communication with the one or more thermoelectric materials so as to also allow electrical current to flow from one portion of the shunt to another portion of the shunt (e.g., thereby providing electrical communication between multiple thermoelectric materials or elements). Heat exchangers can be in thermal communication with the one or more shunts and one or more working fluids of the thermoelectric assembly, module, or system. Various configurations of one or more shunts and one or more heat exchangers can be used (e.g., one or more shunts and one or more heat exchangers can be portions of the same unitary element, one or more shunts can be in electrical communication with one or more heat exchangers, one or more shunts can be electrically isolated from one or more, heat exchangers, one or more shunts can be in direct thermal communication with the thermoelectric elements, one or more shunts can be in direct thermal communication with the one or more heat exchangers, an intervening material can be positioned between the one or more shunts and the one or more heat exchangers). The term “thermal communication” is used herein in its broad and ordinary sense, describing two or more components that are configured to allow heat transfer from one component to another. For example, such thermal communication can be achieved, without loss of generality, by snug contact between surfaces at an interface; one or more heat transfer materials or devices between surfaces; a connection between solid surfaces using a thermally conductive material system, wherein such a system can include pads, thermal grease, paste, one or more working fluids, or other structures with high thermal conductivity between the surfaces (e.g., heat exchangers); other suitable structures; or combinations of structures. Substantial thermal communication can take place between surfaces that are directly connected (e.g., contact each other) or that are indirectly connected via one or more interface materials. Furthermore, as used herein, the words “cold,” “hot,” “cooler,” “hotter” and the like are relative terms, and do not signify a particular temperature or temperature range.

Certain embodiments described herein comprise system-level solutions that minimize thermal losses by integrating both the heat source and the heat sink (e.g., cooling block) with thermoelectric materials and therefore improve system-level efficiency of the thermoelectric devices. Certain embodiments described herein also comprise system-level methods to reduce stresses developed in the thermoelectric materials during operation of the thermoelectric device and by this improve reliability of the device, prevent mechanical failures and performance degradation. Thermoelectric devices and systems used in the power generation modality are disclosed as examples; however the structures and methods described herein can be generalized to thermoelectric devices and systems in the heating/cooling modality as well.

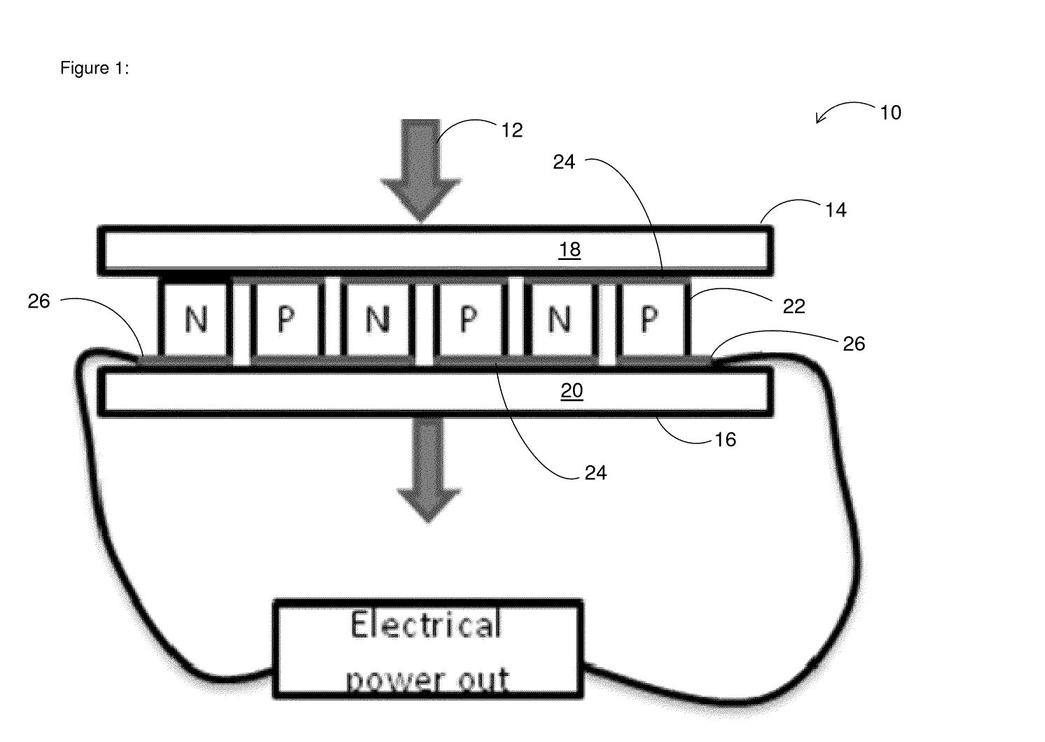

FIG. 1 schematically illustrates an example conventional thermoelectric (TE) device 10 (e.g., a TE module, an elementary cell of a conventional TE system) as used for power generation in which heat flux passes from one side to another. In the TE device 10, the heat flux 12 moves from the hot side 14 to the cold side 16. The TE device 10 comprises a hot-side heat exchanger 18, a cold-side heat exchanger 20, a plurality of TE elements 22 (e.g., including p-type and n-type TE elements), a plurality of shunts 24 providing electrical communication among the plurality of TE elements 22, and electrical contacts 26 through which electrical connection can be made to the plurality of TE elements 22. For example, the TE elements 22 and the shunts 24 can be arranged in a “stonehenge” configuration, as schematically shown in FIG. 1, in which p-type and n-type TE elements 22 alternate with one another and are in electrical communication with one another via shunts 24 which are alternately positioned on a hot side of the TE elements 22 and a cold side of the TE elements 22 such that electrical current can flow serially through the TE elements 22 and the shunts 24 in a serpentine fashion (e.g., vertically through the TE elements 22 of FIG. 1 and horizontally through the shunts 24 of FIG. 1). In certain other embodiments, the TE elements 22 and the shunts 24 are arranged in a “stacked” configuration in which p-type and n-type TE elements 22 alternate with one another and are in electrical communication with one another via shunts 24 that are sandwiched between adjacent p-type and n-type TE elements 22 such that current can flow generally along a single direction through the TE elements 22 and the shunts 24 (e.g., generally parallel directions through the TE elements 22 and the shunts 24).

In FIG. 1, the hot-side heat exchanger 18 and the cold-side heat exchanger 20 are two rigid plates at two distinctly different temperatures and in thermal communication to the shunts 24 on the respective sides of the TE elements 22. Each plate expands as a function of temperature with the expansion along its length given by the product of the plate's coefficient of thermal expansion, the plate's length, and the plate's average temperature increase. During operation, the two rigid plates are both heated, but they are at different temperatures so their expansions occur at different rates. This difference in the thermal expansion of the hot-side heat exchanger 18 and the cold-side heat exchanger 20 creates an increase in a shear load on the TE elements 22. Certain embodiments described herein advantageously provide structures and methods for reducing the shear load on the TE elements 22 (e.g., load in a direction perpendicular to the heat flow).

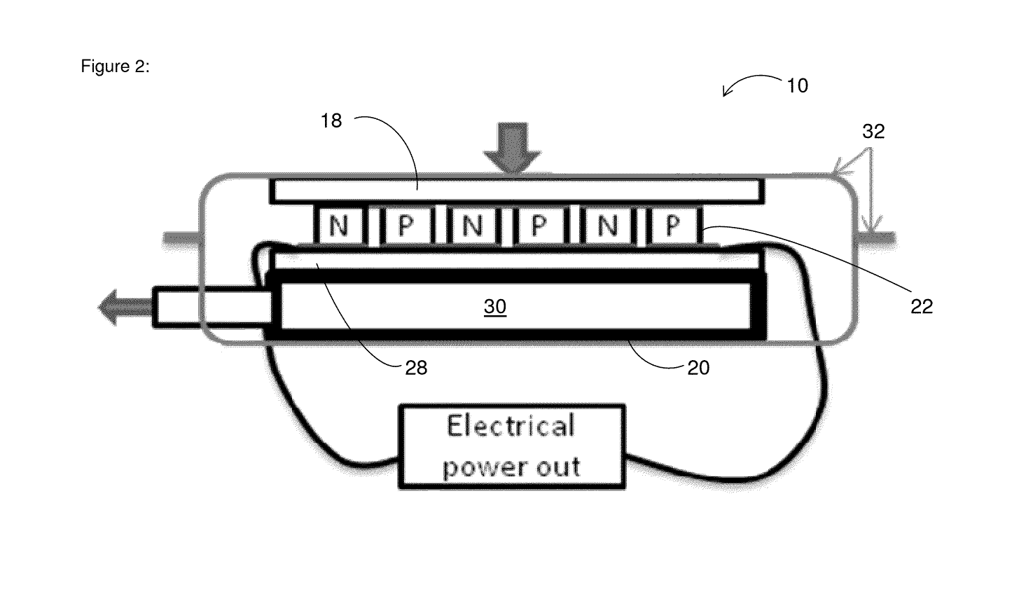

FIG. 2 schematically illustrates an example conventional TE device 10 with encapsulation of the TE elements 22. In FIG. 2, the cold-side heat exchanger 20 comprises a rigid cold plate 28 and a liquid-cooled block 30 in thermal communication with the cold plate 28 (e.g., pressed against the cold plate 28). Encapsulation of the TE elements 22 is provided by an enclosure 32 containing the TE elements 22, the hot-side heat exchanger 18, and the cold-side heat exchanger 20 (e.g., both the cold plate 28 and the block 30). The enclosure 32 can also contain an atmosphere that is substantially inert to the TE elements 22 (e.g., an inert gas, such as a noble gas or nitrogen). As an example, the enclosure 32 can be brazed or welded to an outside portion of one or both of the hot-side heat exchanger 18 and the cold-side heat exchanger 20. This form of the enclosure 32 increases the number of thermal interfaces through which the heat flux flows, thereby increasing the thermal resistance of the overall device and decreasing performance. In addition, this form of the enclosure 32 provides an unwanted thermal path from the hot side to the cold side, via the enclosure 32, that does not go through the TE elements 22, such that some heat bypasses the TE elements 22 and does not contribute to the energy generation. Both the increased number of interfaces and the thermal path for heat bypassing the TE elements contribute to a decrease in performance of such a conventional TE device 10.

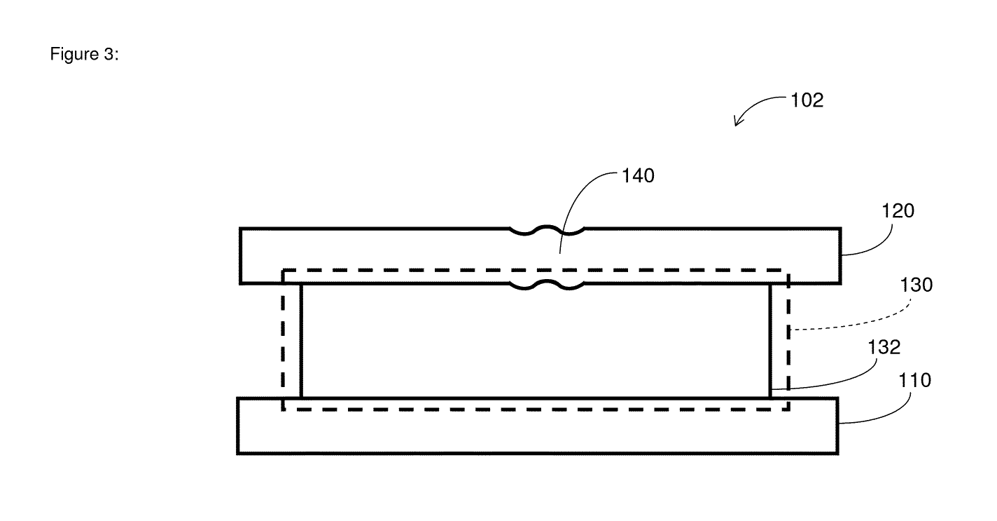

FIG. 3 schematically illustrates an example thermoelectric module 102 in accordance with certain embodiments described herein. For example, a thermoelectric system 100 can comprise one or more such thermoelectric modules 102 for either power generation or for heating and cooling. The thermoelectric module 102 comprises at least one first heat exchanger 110 configured to be in thermal communication with a heat source (e.g., a first working fluid), and at least one second heat exchanger 120 configured to be in thermal communication with a heat sink (e.g., a second working fluid). The thermoelectric module 102 further comprises at least one thermoelectric assembly 130 comprising a plurality of thermoelectric elements 132 sealed within an environment comprising a gas. For example, the at least one thermoelectric assembly 130 can comprise a plurality of thermoelectric elements and a plurality of shunts in either a stonehenge configuration or a stacked configuration. The at least one thermoelectric assembly 130 is mechanically coupled to the at least one first heat exchanger 110 and mechanically coupled to the at least one second heat exchanger 120. The at least one thermoelectric assembly 130 is sandwiched between the at least one first heat exchanger 110 and the at least one second heat exchanger 120. The at least one second heat exchanger 120 comprises at least one mechanically compliant element 140 configured to flex in response to at least one dimensional change of the at least one thermoelectric assembly 130 due to thermal expansion or contraction (e.g., change of a length, width, thickness, or shape of one or mom components of the thermoelectric module or system). In certain embodiments the at least one dimensional change comprises elongation of at least some thermoelectric elements of the plurality of thermoelectric elements 132.

In the power generation mode, heat received by the first heat exchanger 110 from the heat source (e.g., from a hot first working fluid, from a hot solid, or from radiation) can be converted by the thermoelectric module 102 into electricity. Excess heat (e.g., heat that is not converted into electricity) can be removed by the second heat exchanger 120 to the heat sink (e.g., to a cold second working fluid, to a cold solid, or to another heat sink). The plurality of thermoelectric elements 132 are sealed within an environment containing an atmosphere that is substantially inert to the thermoelectric elements 132 (e.g., an inert gas, such as a noble gas or nitrogen).

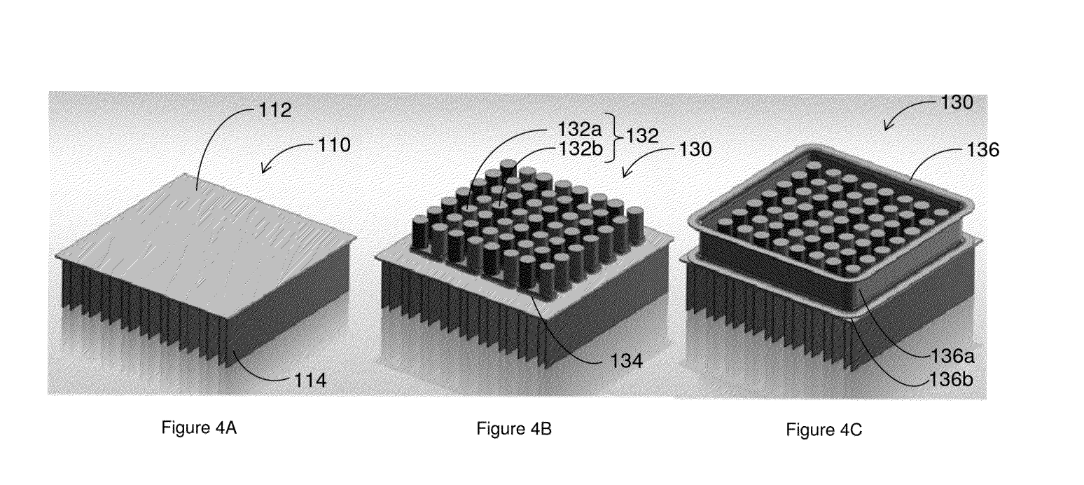

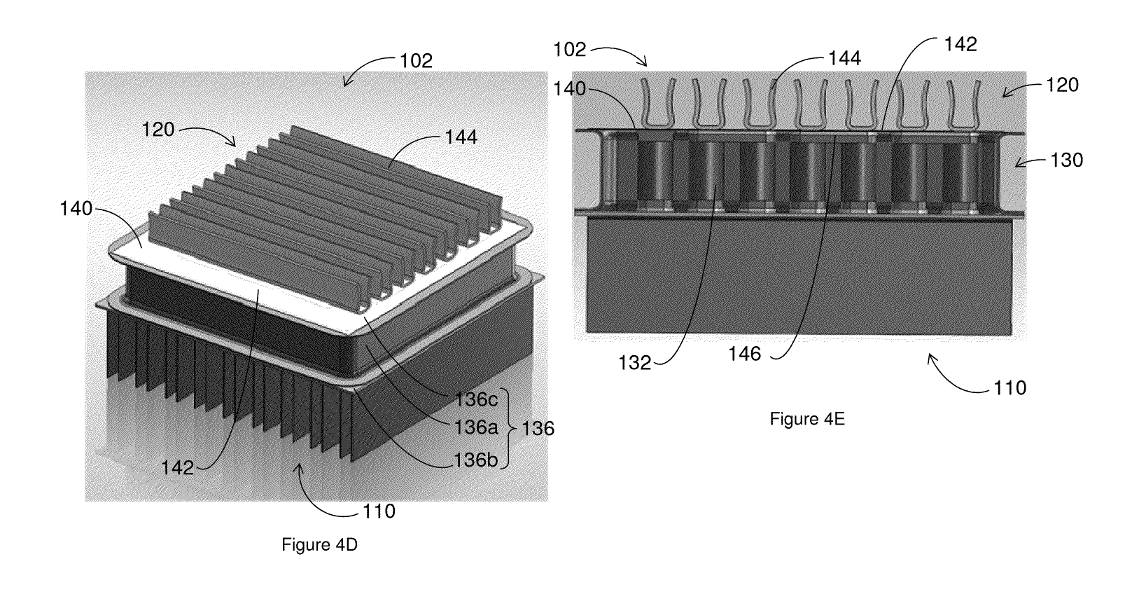

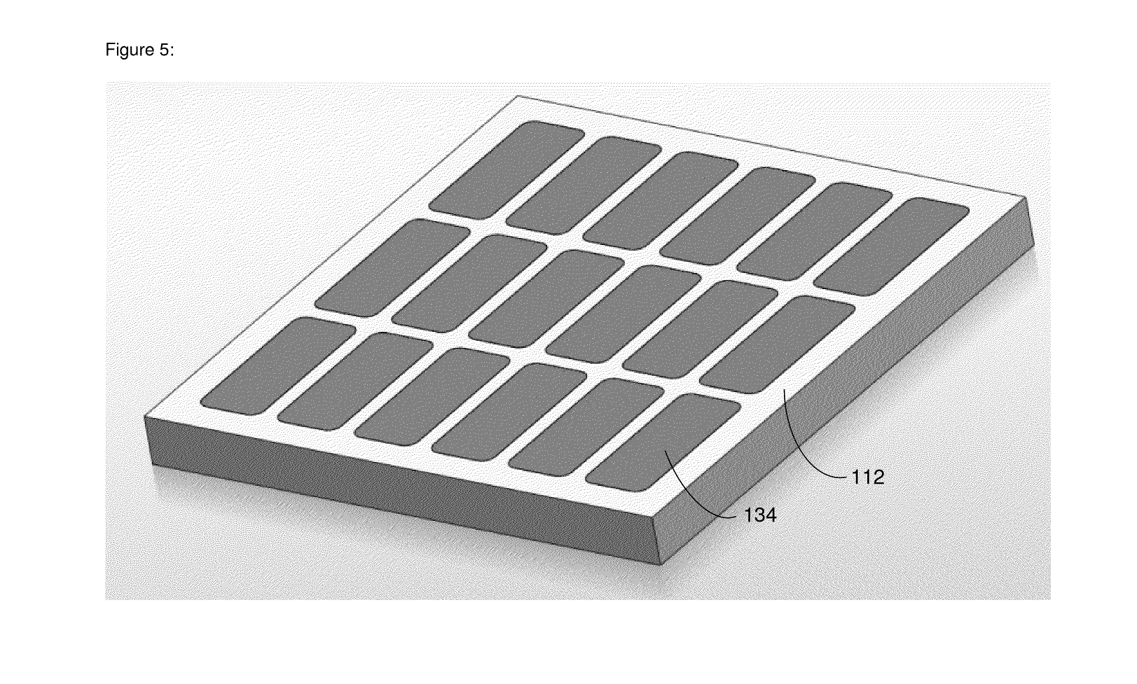

FIGS. 4A-4E schematically illustrates an example thermoelectric module 102 in various stages of fabrication and which is compatible for use in a thermoelectric system 100 in accordance with certain embodiments described herein. The example thermoelectric module 102 can be in thermal communication with a heat source (e.g., a solid, a liquid, a gas, or a combination of two or more of a solid, a liquid, and a gas) and with a heat sink (e.g., a solid, a liquid, a gas, or a combination of two or more of a solid, a liquid, and a gas). While the example thermoelectric module 102 is described as using a hot gas as the heat source (e.g., first working fluid) and a cold liquid as the heat sink (e.g., second working fluid), other configurations are also compatible with certain embodiments described herein. For example, the thermoelectric module 102 of FIGS. 4A-4E can be used with a first working fluid that comprises a liquid, a gas, or a combination of a liquid and a gas, and a second working fluid that comprises a liquid, a gas, or a combination of a liquid and a gas. Furthermore, in other examples, the thermoelectric module 102 can be used with one or more of the hot side or the cold side in thermal communication with a solid surface rather than a liquid or a gas.

As shown in FIG. 4A, the at least one first heat exchanger 110 can comprise a base plate 112 and a first plurality of fins 114 (e.g., brazed or otherwise directly bonded to the base plate 102) configured to be in thermal communication with the first working fluid. In certain embodiments, the base plate 112 and the first plurality of fins 114 can be formed as a mono-block by casting, pressing, or extrusion. In certain embodiments, the base plate 112 comprises a material with a low coefficient of thermal expansion (CTE), examples of which include, but are not limited to, silicon carbide and aluminum silicon carbide.

As shown in FIG. 4B, the at least one thermoelectric assembly 130 can comprise a plurality of thermoelectric elements 132 (e.g., p-type thermoelectric elements 132a and n-type thermoelectric elements 132b) and a first plurality of shunts 134 bonded to the thermoelectric elements 132 to form at least a portion of the circuit through which electrical current is intended to flow through the plurality of thermoelectric elements 132. The first plurality of shunts 134 can be bonded to the at least one first heat exchanger 110 (e.g., placed on and bonded to the base plate 112, by brazing, sintering, or gluing). For example, the first plurality of shunts 134 of FIG. 4B can be on the base plate 112 of the at least one first heat exchanger 110 and one p-type thermoelectric element 132a and one n-type thermoelectric element 132b are bonded to corresponding portions of a shunt 134, thereby forming a portion of an electrical circuit for a stonehenge configuration. Alternatively, as schematically illustrated in FIG. 5, the first plurality of shunts 134 can comprise conductive integral portions of the at least one heat exchanger 110 that are configured to facilitate the desired circuit for electrical current to flow through the at least one thermoelectric assembly 130. For example, the base plate 112 can comprise a composite material in which electrically conductive pads (e.g., nickel) are bonded to a substrate material (e.g., a low CTE material such as silicon carbide or aluminum silicon carbide) to serve as the first plurality of shunts 134.

In certain embodiments, the portions of the thermoelectric elements 132 opposite to the first plurality of shunts 134 are configured to be substantially aligned with one another (e.g., in a common plane parallel to the base plate 112). Such alignment can be advantageous to provide a substantially flat surface for the at least one second heat exchanger 120 and to equally distribute mechanical loads. For example, after placing the thermoelectric elements 132 and the first plurality of shunts 134 on the base plate 112, the portions of the thermoelectric elements 132 opposite to the first plurality of shunts 134 can be lapped to have these portions of the thermoelectric elements 132 aligned with one another. For another example, thermoelectric elements 132 and the first plurality of shunts 134 having the desired dimensions can be bonded together and to the at least one first heat exchanger 110 such that the portions of the thermoelectric elements 132 opposite to the first plurality of shunts 134 are aligned with one another (e.g., in a common plane parallel to the base plate 112).

As shown in FIG. 4C, 4D, and 4E, the at least one thermoelectric assembly 130 can further comprise an enclosure 136. The enclosure 136 can be configured to contain the thermoelectric elements 132 in an environment having an atmosphere that is substantially inert to the thermoelectric elements 132 (e.g., an inert gas, such as a noble gas or nitrogen). The enclosure 136 can comprise a first portion 136a, a second portion 136b, and a third portion 136c. The first portion 136a can be substantially surrounding the thermoelectric elements 132, the first plurality of shunts 134, and a second plurality of shunts 138 (shown in FIG. 4E) of the at least one thermoelectric assembly 130. The second portion 136b can comprise a portion of the at least one first heat exchanger 110 (e.g., the base plate 112) at one side of the at least one thermoelectric assembly 130. For example, the first portion 136a can be gas-impermeable and bonded (e.g., by brazing or welding) to the base plate 112, which is also gas-impermeable, to form a hermetic seal between the first portion 136a and the second portion 136b. Such a configuration can advantageously reduce the number of thermal interfaces between the heat source and the at least one thermoelectric assembly 130 (e.g., the plurality of thermoelectric elements 132) to improve device performance. As discussed more fully below, the at least one mechanically compliant element 140 can comprise the third portion 136c.

The material for the first portion 136a can have a coefficient of thermal expansion (CTE) that is lower than that of the thermoelectric elements 132. In certain such embodiments, as the thermoelectric elements 132 and the first portion 136a are heated during operation of the thermoelectric module 102, the thermoelectric elements 132 will expand more than will the first portion 136a such that the thermoelectric elements 132 remain in compression (e.g., the compressive force or pressure applied to the thermoelectric elements 132 in a direction perpendicular to the at least one first heat exchanger 110 and the at least one second heat exchanger 120) will increase with increasing temperature. The choice of material for the first portion 136a can depend on the material being used for the thermoelectric elements 132. For example, when the thermoelectric elements 132 comprise Bi₂Te₃, the material for the first portion 136a can comprise an aluminum alloy, when the thermoelectric elements 132 comprise PbTe, the material for the first portion 136a can comprise stainless steel (e.g., having a CTE equal to 19E-6 1/K), and when the thermoelectric elements 132 comprise a material from the class of skutterudites, the material for the first portion 136a can have a CTE less than 13E-6 1/K (e.g., steel alloy).

In certain embodiments, the first portion 136a is configured to flex and to have a restoring force such that a pressure applied to the thermoelectric elements 132 due to thermal expansion is regulated. For example, the first portion 136a can comprise one or more walls having a bowed or “C” cross-section geometry configured to provide such flexure. These bowed walls of the first portion 136a can be either concave (e.g., bowed inwardly towards the environment) or convex (e.g., bowed outwardly away from the environment).

FIG. 4D schematically illustrates a perspective view and FIG. 4E schematically illustrates a cross-sectional view of an example thermoelectric module 102 with the at least one second heat exchanger 120 in accordance with certain embodiments described herein. The at least one second heat exchanger 120 comprises at least one mechanically compliant element 140 configured to flex in response to at least one dimensional change of the at least one thermoelectric assembly 130 due to thermal expansion or contraction. The at least one mechanically compliant element can be configured to reduce a shear load on the plurality of thermoelectric elements 132.

For example, as shown in FIGS. 4D and 4E, the at least one mechanically compliant element 140 can comprise a membrane 142, and at least a portion of the membrane 142 can be configured to flex in response to the at least one dimensional change of the at least one thermoelectric assembly 130. For example, the portion of the membrane 142 can be configured to stretch in a direction perpendicular to a direction of heat flow from the at least one first heat exchanger 110 to the at least one second heat exchanger 120 (e.g., in response to a dimensional change in the spacing between adjacent thermoelectric elements 132 due to thermal expansion or contraction). The membrane 142 can be mounted to the at least one thermoelectric assembly 130. The at least one second heat exchanger 120 can further comprise a second plurality of fins 144 in contact with the membrane 142.

The membrane 142 can be bonded to the first portion 136a of the enclosure 136 to form a hermetic seal between the first portion 136a and the membrane 142 (e.g., by gluing, soldering, brazing, or welding). The membrane 142 can form a third portion 136c of the enclosure 136 which contains the thermoelectric elements 132, the first plurality of shunts 134 at the hot side of the thermoelectric elements 132, and the second plurality of shunts 138 at the cold side of the thermoelectric elements 132.

The membrane 142 can comprise the third portion 136c of the enclosure 136 to at least partially bound the environment in which the thermoelectric elements 132 are sealed. In certain such embodiments, the environment comprises an inert gas atmosphere (e.g., a noble gas or nitrogen) and the membrane 142 comprises a gas-impermeable material to serve as a barrier (e.g., between the environment and the second working fluid) which, along with the first portion 136a and the second portion 136b, confines the inert gas atmosphere and the thermoelectric elements 132 within the at least one thermoelectric assembly 130. In this way, the membrane 142 can advantageously seal the thermoelectric elements 132 in the inert gas atmosphere within the enclosure 136 and can prevent gas diffusion (e.g., from the second working fluid) to the encapsulated area within the enclosure 136.

The membrane 142 can comprise an elastic material, examples of which include but are not limited to, elastic polymers that will easily deform at room temperature and will prevent diffusion of gases and liquids across the membrane 142 (e.g., high barrier plastics). The membrane 142 can provide sufficient compliance to reduce shear stresses on the thermoelectric elements 132 that would otherwise exist if the membrane 142 were rigid. In certain embodiments, the membrane 142 comprises a laminate structure comprising a plurality of layers. For example, the membrane 142 can comprise a first metal layer (e.g., comprising copper, aluminum, nickel, or an alloy of one or more of copper, aluminum, and nickel), a second metal layer (e.g., comprising copper, aluminum, nickel, or an alloy of one or more of copper, aluminum, and nickel), and a dielectric layer (e.g., Kapton®) between the first metal layer and the second metal layer. The first and second metal layers can be sufficiently thin such that the membrane 142 will easily flex under forces generated by the thermal expansion or contraction of components of the thermoelectric module 102 (e.g., the thermoelectric elements 132, the enclosure 136, the at least one first heat exchanger 110, the at least one second heat exchanger 120) while providing the impermeable gas barrier to confine the inert gas atmosphere within the at least one thermoelectric assembly 130. For example, the membrane 142 can comprise a Kapton® layer cladded on one or both sides by a copper layer, which is brazed or soldered onto the first portion 136a of the enclosure 136 to provide a hermetic seal.

In certain embodiments, at least a portion of the membrane 142 (e.g., between at least some adjacent thermoelectric elements of the plurality of thermoelectric elements 132) is sufficiently elastic such that the membrane 142 will elongate in the direction perpendicular to the heat flow (e.g., in a direction along the at least one second heat exchanger 120, in a direction along the direction of flow of the second working fluid). By flexing in this direction in response to the at least one dimensional change of the at least one thermoelectric assembly 130, the membrane 142 can advantageously reduce the shear load on the thermoelectric elements 132.

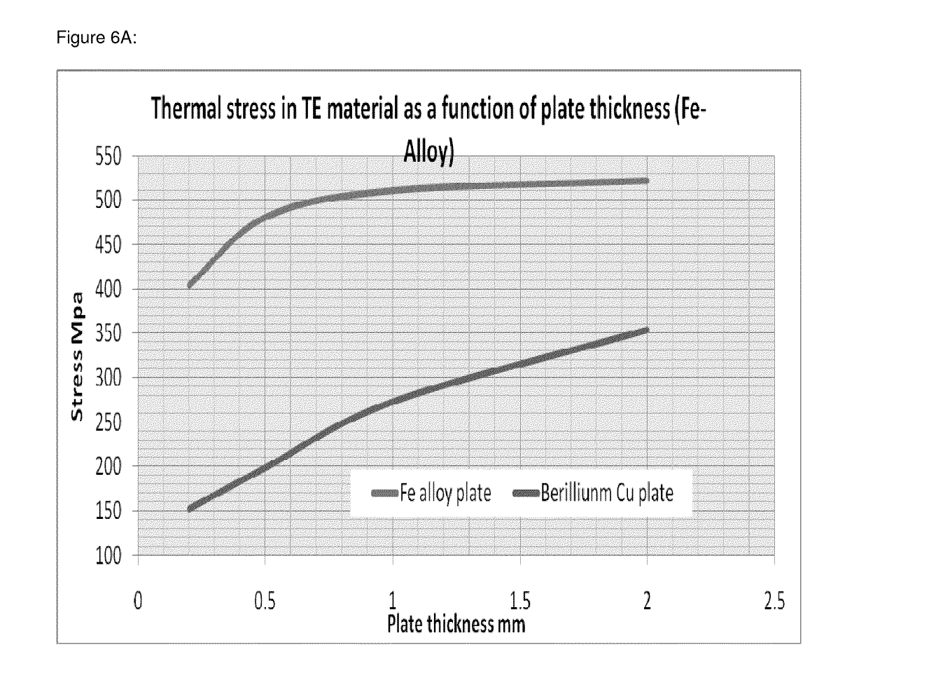

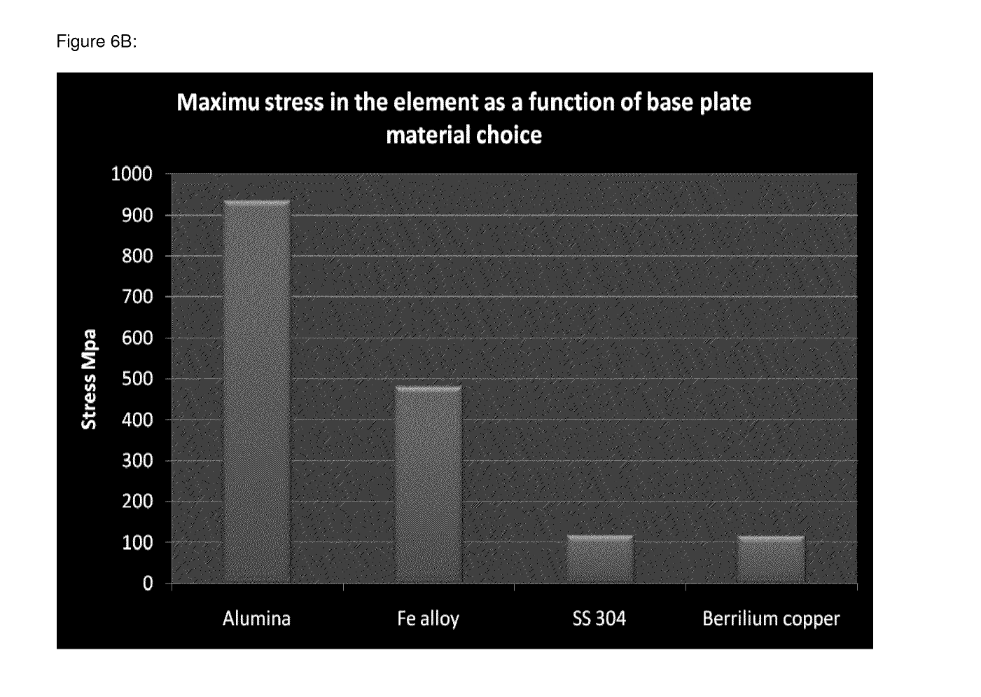

FIGS. 6A and 6B shows the results of a finite-element-analysis (FEA) calculation of the shear stress on thermoelectric elements in a configuration similar to one shown in FIGS. 4A-4E. In this FEA calculation, the membrane 142 (e.g., plate) was selected to comprise a variety of materials at a variety of thicknesses. As shown in FIG. 6A, for both a beryllium-copper alloy plate and an iron alloy plate, the thermal stress experienced by the thermoelectric elements generally decreases with decreasing thickness of the plate. Since the beryllium-copper alloy is less rigid than is the iron alloy (e.g., the Be-Cu alloy has a lower modulus of elasticity than does the Fe alloy), the stress experienced by the thermoelectric elements is less for the Be-Cu alloy membrane than for the Fe alloy membrane. This example calculation illustrates the effect of stress reduction and improved reliability as the membrane 142 becomes thinner and as the membrane material is selected to be less rigid (e.g., to have a lower modulus of elasticity). The histogram of FIG. 6B shows that the conventionally-used materials for base plates (e.g., alumina) have very high moduli of elasticity, resulting in high stresses experienced by the thermoelectric elements. In certain embodiments described herein, the membrane 142 can be selected to comprise one or more materials with low elastic moduli (e.g., Cu, Al, or Ni, and their alloys).

In certain embodiments, the membrane 142 is configured to be in direct contact with the second working fluid. The membrane 142 can directly separate the second working fluid from the inert gas atmosphere within the enclosure 136 while allowing heat flow between the at least one thermoelectric assembly 130 and the second working fluid. By having the second working fluid directly on the top of the second plurality of shunts 146, as shown in FIG. 4E, it is possible to reduce thermal interface resistance and to further improve device performance. As compared to conventional encapsulated thermoelectric modules (see, e.g., FIG. 2), the thermoelectric module 102 shown in FIGS. 4D and 4E, in which the membrane 142 is in direct contact with the second working fluid and with the second plurality of shunts 146 (as well as serving as a gas-impermeable barrier for the inert gas environment, advantageously reduces the number of thermal interfaces (e.g., by 3 as compared to the configuration of FIG. 2, with two between the heat source and the thermoelectric elements and one between the cold plate and the heat sink).

As shown in FIGS. 4D and 4E, the second plurality of fins 144 can be coupled to the membrane 142. The second plurality of fins 144 is configured to be in thermal communication with the second working fluid (e.g., increasing the surface area in contact with the second working fluid). For example, the first plurality of fins 114 can extend along a first direction and the second plurality of fins 144 can extend along a second direction generally perpendicular to the first direction. In certain embodiments, the second plurality of fins 144 are positioned across the membrane 142 and directly opposite from the second plurality of shunts 146 (see, e.g., FIG. 4E).

In certain embodiments, the membrane 142 can comprise the second plurality of shunts 146. For example, the membrane 142 can comprise conductive integral portions (e.g., a conductive metal layer) that are configured to provide electrical communication among the plurality of thermoelectric elements 132 to facilitate the desired circuit for electrical current to flow through the at least one thermoelectric assembly 130). For another example, the membrane 142 can comprise a composite material in which the second plurality of shunts 146 is potted in a thermally conductive and elastic epoxy. By having the epoxy yield under stress and deform, the membrane 142 can advantageously reduce the shear loads on the thermoelectric elements 132.

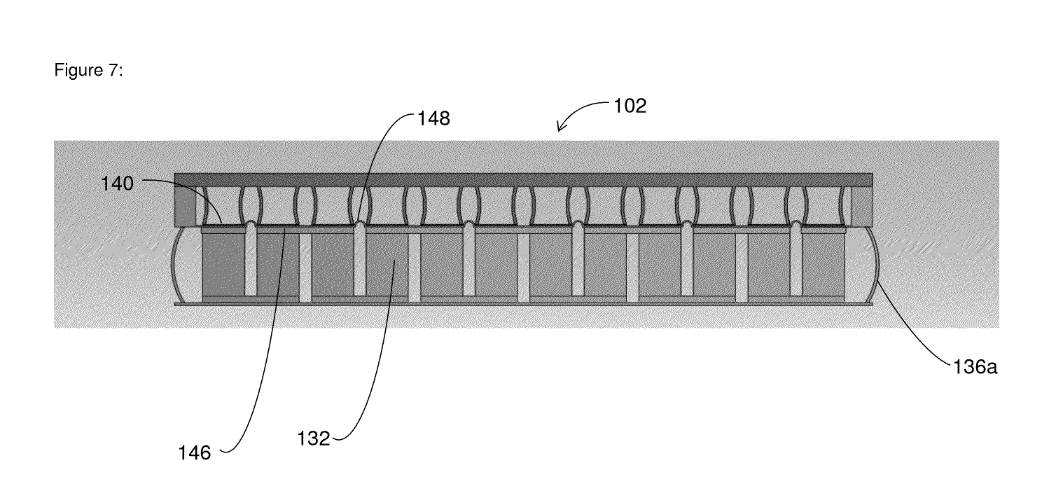

FIG. 7 schematically illustrates a cross-sectional view of another example thermoelectric module 102 comprising at least one mechanically compliant element 140 in accordance with certain embodiments described herein. The at least one mechanically compliant element 140 comprises a plurality of flexible portions 148 positioned between at least some of the thermoelectric elements 132 (e.g., between two adjacent shunts of the second plurality of shunts 146). For example, the flexible portions 148 can comprise bent portions of a membrane 142 as described above. The membrane 142 can be formed by pressing or stamping a thin metal foil into a shape (e.g., wavy) having the flexible portions 148. The flexible portions 148 can be configured to elongate (e.g., become less bent) due to axial load. In this way, the flexibility of the membrane 142 can be improved and the stress expected to be experienced by the thermoelectric elements 132 can be reduced. FIG. 7 also shows a first portion 136a of the enclosure 136 with bowed walls that are convex and which can provide a restoring force such that a pressure applied to the thermoelectric elements 132 due to thermal expansion is regulated.

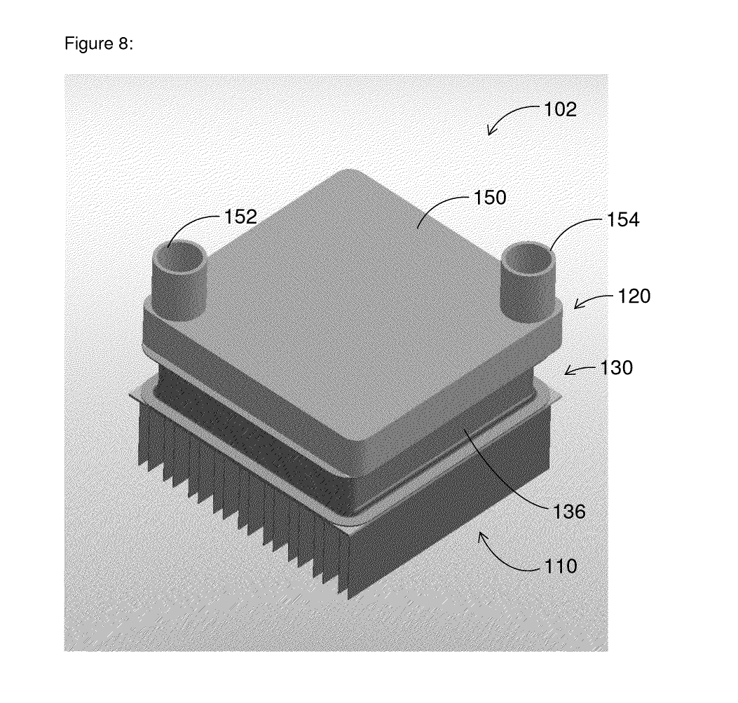

FIG. 8 schematically illustrates the thermoelectric module 102 of FIGS. 4A-4E with a cooling block housing 150 enclosing the second plurality of fins 144. The housing 150, along with the membrane 142, forms a region configured to allow the second working fluid to flow through and to be in thermal communication with the second plurality of fins 144. The housing 150 can comprise an inlet 152 and an outlet 154. The housing 150 can be coupled to portions of the first portion 136a of the enclosure 136 (e.g., brazed, welded, or glued) to form a seal that is impermeable to the second working fluid.

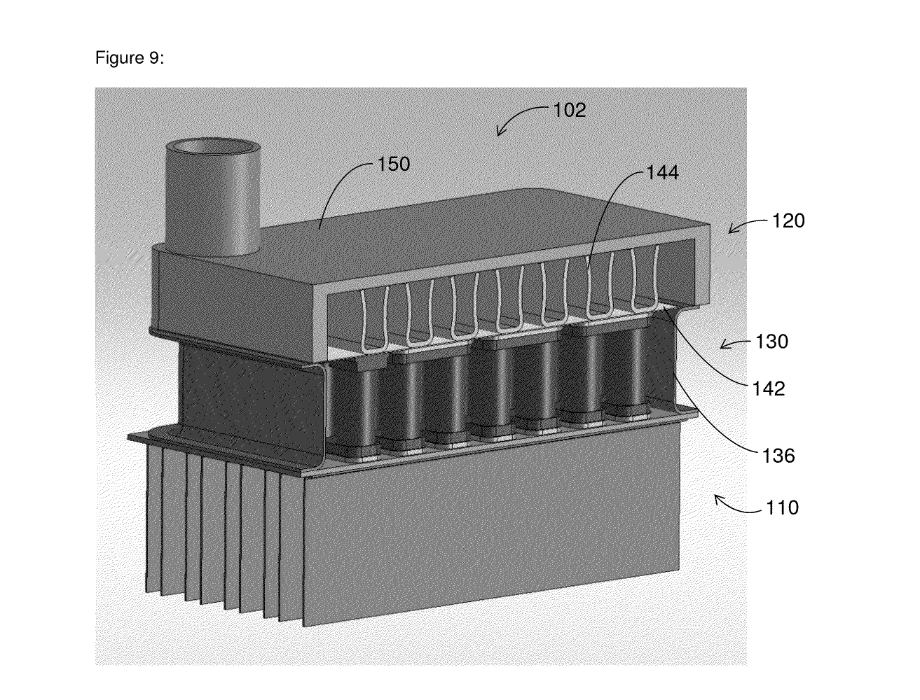

In certain embodiments, the thermoelectric module 102 comprises a plurality of springs mechanically coupled to the membrane 142 and configured to apply a restoring force to the membrane 142 in response to the at least one dimensional change of the at least one thermoelectric assembly 130. The springs can be advantageously configured to suppress buckling of the membrane 142 and to control the load on the thermoelectric elements 132. For example, FIG. 9 schematically illustrates a cross-sectional view of a thermoelectric module 102 comprising a second plurality of fins 144 coupled to the membrane 142 and in contact with the cooling block housing 150. Upon thermal expansion of the thermoelectric elements 132, the second plurality of fins 144 are compressed between the thermoelectric elements 132 and the housing 150 and can provide a restoring force to the membrane 142 while keeping the thermoelectric elements under compression (e.g., applying a compressive force to the plurality of thermoelectric elements 132). For example, as schematically illustrated in FIG. 9, the second plurality of fins 144 are “U”-shaped with fins 144 which are configured to flex such that their ends splay apart from one another when the fins 144 are compressed by thermal expansion of the thermoelectric elements 132. For another example, the fins 144 have bowed walls which are configured to flex such that the walls bow further when the fins 144 are compressed by thermal expansion of the thermoelectric elements 132.

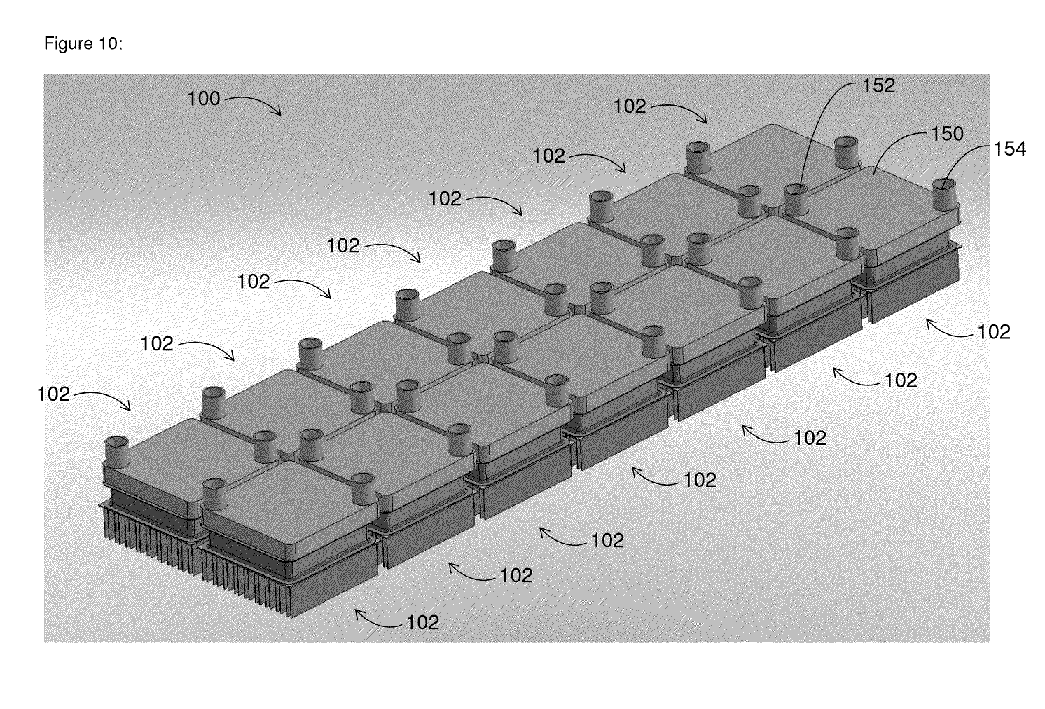

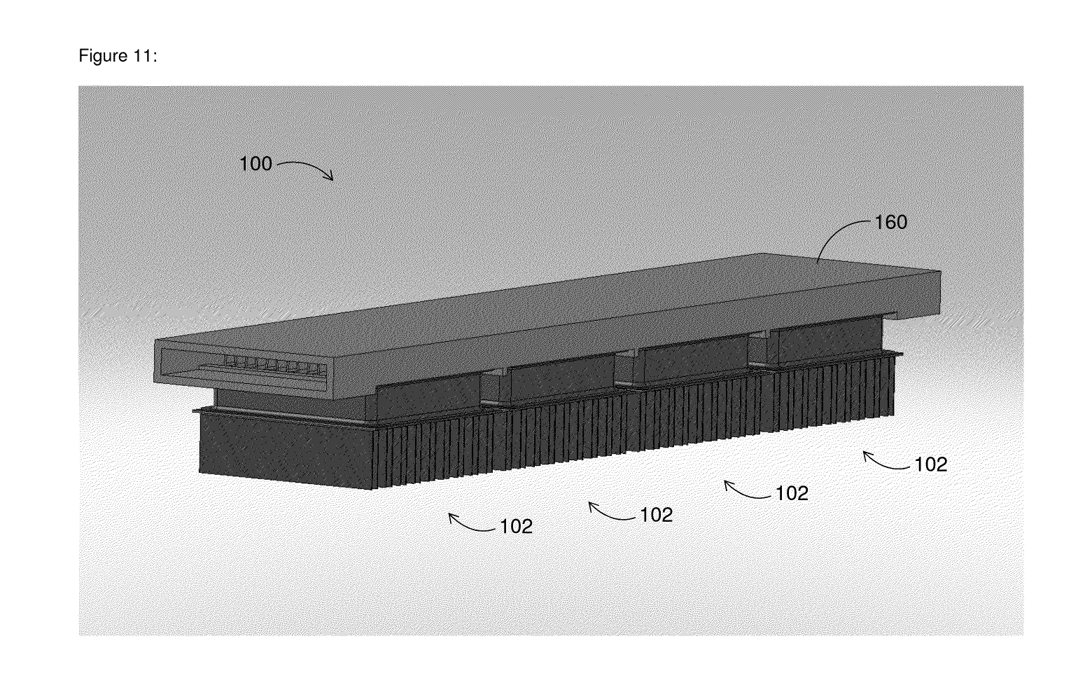

FIGS. 10 and 11 schematically illustrate example thermoelectric systems 100 comprising a plurality of thermoelectric modules 102 in accordance with certain embodiments described herein. In FIGS. 10 and 11, the at least one thermoelectric assembly 130 comprises a plurality of thermoelectric assemblies 130, the at least one membrane 142 comprises a plurality of membranes 142, and the thermoelectric modules 102 are arranged to utilize a common first working fluid in thermal communication with the first heat exchangers 110 of the plurality of thermoelectric modules 102.

In FIG. 10, the inlets 152 and the outlets 154 of the cooling block housings 150 of the plurality of thermoelectric modules 102 can be configured such that the housings 150 are in series fluidic communication, in parallel fluidic communication, or a combination of series and parallel fluidic communication with one another. In certain such embodiments, the thermoelectric modules 102 are arranged in an array in which the thermoelectric modules 102 are thermally connected in parallel and are electrically connected in series.

In FIG. 11, the at least one second heat exchanger 120 further comprises a fluid conduit 160 comprising the plurality of membranes 142 (not visible in FIG. 11). An example fluid conduit 160 can include, but is not limited to, an extruded, aluminum alloy tube. Each membrane 142 is in thermal communication with a corresponding thermoelectric assembly 130 of the plurality of thermoelectric assemblies 130. The second working fluid flows through the fluid conduit 160 and is in thermal communication with each membrane 142 of the plurality of membranes 142 sequentially. By integrating the thermoelectric modules 102 with the single fluid conduit 160, certain such embodiments advantageously reduce the number of fluid connections (e.g., inlets 152 and outlets 154) as compared to FIG. 10, and correspondingly improve the performance.

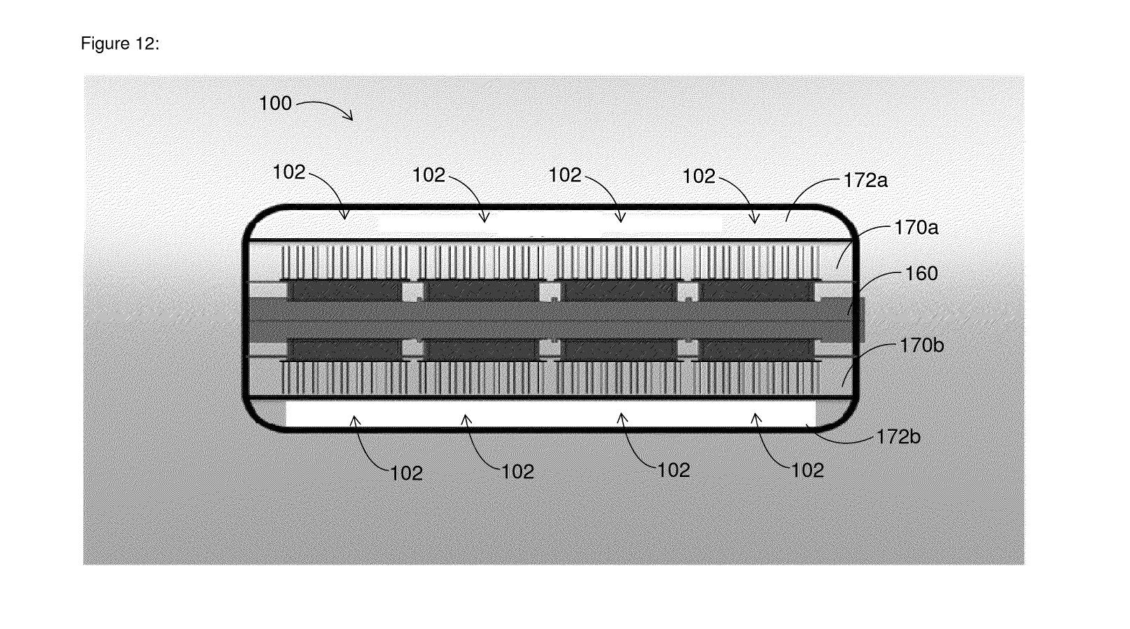

FIG. 12 schematically illustrates another example thermoelectric system 100 comprising a plurality of thermoelectric modules 102 in accordance with certain embodiments described herein. The plurality of thermoelectric modules 102 are arranged to have a common second working fluid flowing through a central fluid conduit 160 and the plurality of membranes 142 (not shown in FIG. 12) are in thermal communication with the second working fluid. A first set of the thermoelectric modules 102 have their first heat exchangers 110 in thermal communication with a first working fluid flowing through a first region 170a and a second set of the thermoelectric modules 102 have their first heat exchangers 110 in thermal communication with the first working fluid flowing through a second region 170b. The thermoelectric system 100 of FIG. 12 further comprises at least one bypass region 172 (e.g., a first bypass region 172a positioned between the first region 170a and the surrounding environment and a second bypass region 172b positioned between the second region 170b and the surrounding environment). The at least one bypass region 172 is configured to thermally insulate the at least one first heat exchanger 110 (e.g., the fins 114) from the surrounding environment. Since the surrounding environment is typically at much lower temperatures than is the first working fluid, when there is not gas flowing through the at least one bypass region 172, the at least one bypass region 172 can advantageously act as a heat transfer barrier and can reduce unwanted heat losses from the first working fluid.

The thermoelectric system 100 is configured to selectively allow at least a portion of the first working fluid to flow through the bypass region 170 upon a temperature of the first working fluid exceeding a predetermined temperature. For example, if the temperature of the first working fluid reaches a temperature expected to cause damage to the thermoelectric elements 132 or other portions of the thermoelectric system 100, a control sub-system of the thermoelectric system 100 can divert at least a portion of the first working fluid to flow through the at least one bypass region. By flowing the hot first working fluid along the surfaces of the bypass regions 172a, 172b in contact with the surrounding environment, certain embodiments described herein advantageously cool down the first working fluid more effectively and protect the thermoelectric system 100 from damage due to overheating, thereby improving device reliability.

Certain embodiments described above advantageously provide structures and methods for reducing the number of thermal interfaces of a TE device with encapsulation, to improve the device performance. Certain embodiments described above advantageously provide structures and methods for providing cooling liquid to the cold side of the enclosed TE device, to improve the device reliability. Certain embodiments described above advantageously improve reliability and performance of TE devices by integrating components together at the system level.

Certain embodiments described above allow for reduced shear loads on TE materials by use of elastic membranes on the cold side. Elasticity can be achieved by design of elastic membrane geometries and materials choice. Certain embodiments described above enable control of pressure on TE materials by use of elastic spring-loading fins on the cold side. Certain embodiments described above allow reduction of the number of thermal interfaces as compared to conventional thermoelectric modules by means of integrating fins on the hot base plate and liquid cooling directly on the cold side of the TE element without additional interfaces. Certain embodiments described above allow for reduced shear on TE materials by designing a composite base plate from a low CTE matrix and low modulus of elasticity shunt materials. Certain embodiments described above allow for integration of thermoelectric modules on a single cold tube, reducing the design complexity and improving the performance.

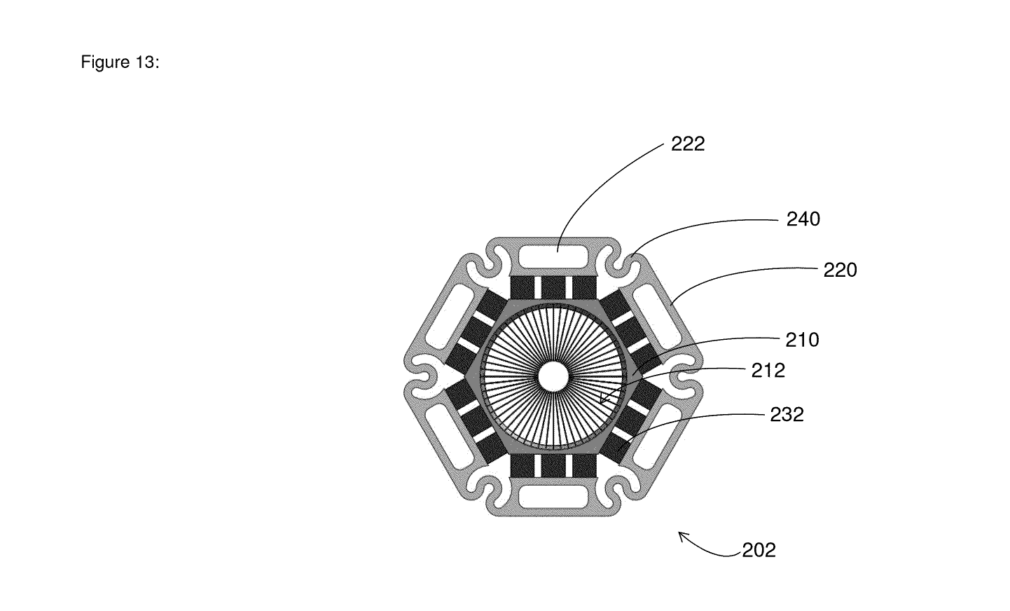

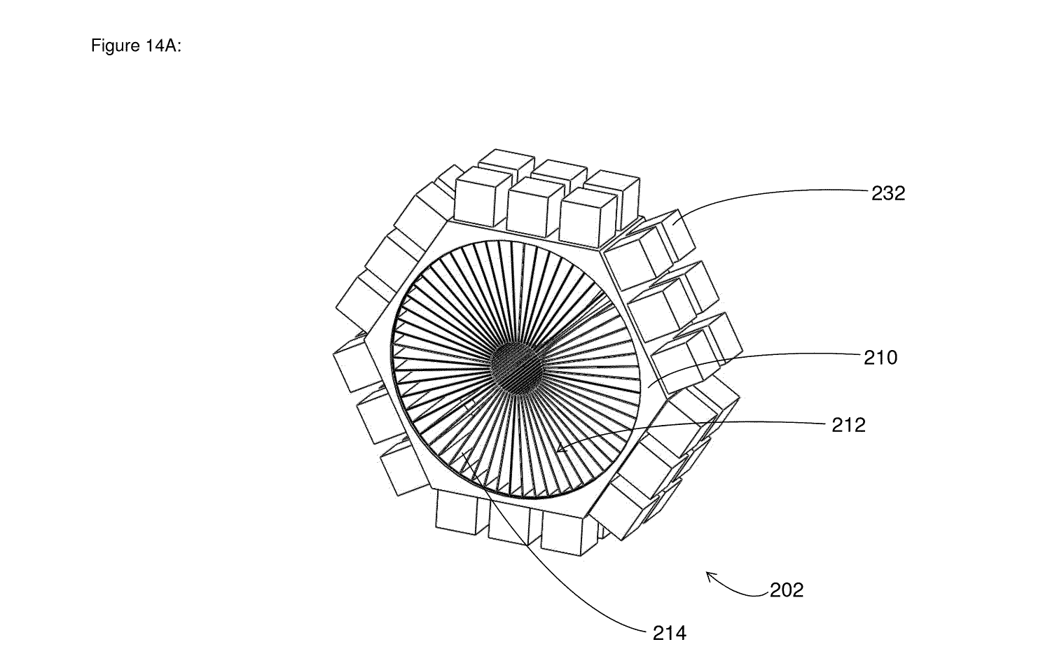

FIG. 13 schematically illustrates another example thermoelectric assembly 202 in accordance with certain embodiments described herein. For example, a thermoelectric system 200 can comprise one or more thermoelectric modules comprising a plurality of such thermoelectric assemblies 202 for either power generation or for heating and cooling. The thermoelectric assembly 202 comprises at least one first heat exchanger 210 configured to be in thermal communication with a first working fluid, and at least one second heat exchanger 220 configured to be in thermal communication with a second working fluid. The thermoelectric assembly 202 further comprises a plurality of thermoelectric elements 232 (e.g., with a plurality of shunts in either a stonehenge configuration or a stacked configuration). As described more fully below, a thermoelectric system 200 comprising a plurality of such thermoelectric assemblies 202 can have the plurality of thermoelectric elements 232 sealed within an environment comprising a gas. The thermoelectric elements 232 are mechanically coupled to the at least one first heat exchanger 210 and mechanically coupled to the at least one second heat exchanger 220. The thermoelectric elements 232 are sandwiched between the at least one first heat exchanger 210 and the at least one second heat exchanger 220. The at least one second heat exchanger 220 comprises at least one mechanically compliant element 240 configured to flex in response to at least one dimensional change of the at least one thermoelectric assembly 202 due to thermal expansion or contraction (e.g., change of a length, width, thickness, or shape of one or more components of the thermoelectric module or system). In certain embodiments the at least one dimensional change comprises elongation of at least some thermoelectric elements of the plurality of thermoelectric elements 232.

In the power generation mode, heat received by the at least one first heat exchanger 210 (e.g., from a hot first working fluid, from a hot solid, or from radiation) can be converted by the thermoelectric assembly 202 into electricity. Excess heat (e.g., heat that is not converted into electricity) can be removed by the at least one second heat exchanger 220 (e.g., to a cold second working fluid, to a cold solid, or to another heat sink). The plurality of thermoelectric elements 232 of the thermoelectric system 200 can be sealed within an environment containing an atmosphere that is substantially inert to the thermoelectric elements 232 (e.g., an inert gas, such as a noble gas or nitrogen).

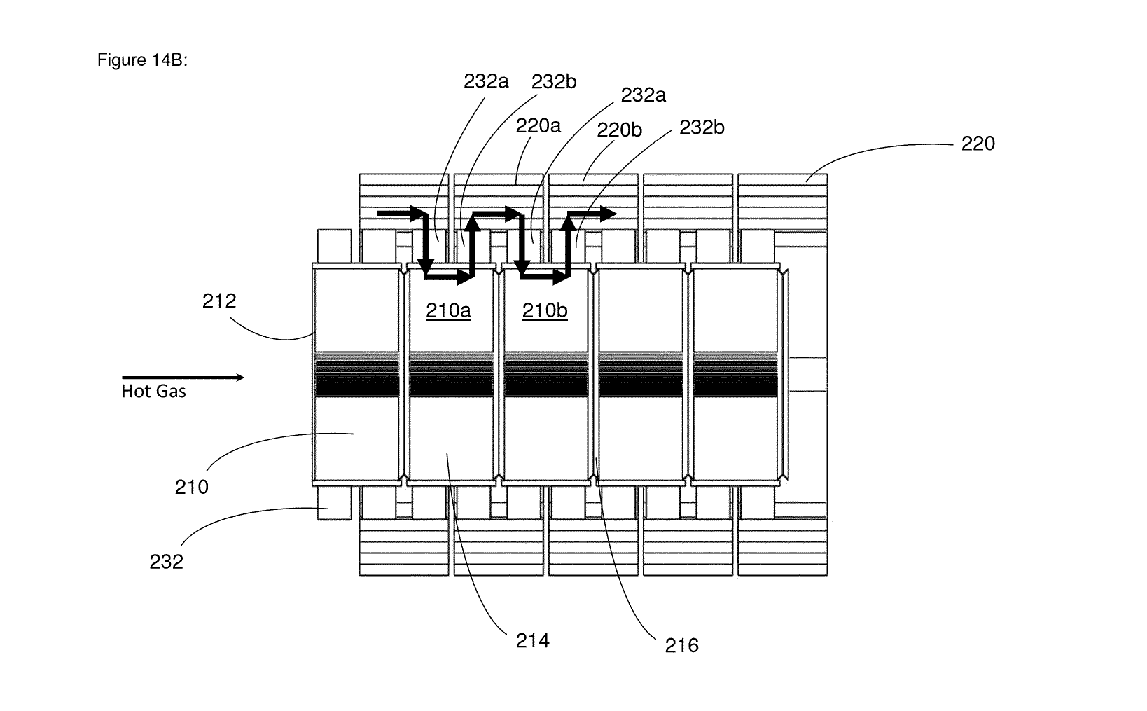

FIG. 14A schematically illustrates a perspective view of a portion of the example thermoelectric assembly 202 of FIG. 13 in accordance with certain embodiments described herein. FIG. 14B schematically illustrates a cross-sectional view of a thermoelectric system 200 comprising a plurality of the example thermoelectric assemblies 202 of FIG. 13 in accordance with certain embodiments described herein. The example thermoelectric assembly 202 can be in thermal communication with a heat source (e.g., a solid, a liquid, a gas, or a combination of two or more of a solid, a liquid, and a gas) and with a heat sink (e.g., a solid, a liquid, a gas, or a combination of two or more of a solid, a liquid, and a gas). While the example thermoelectric assembly 202 is described as using a hot gas as the heat source (e.g., first working fluid) and a cold liquid as the heat sink (e.g., second working fluid), other configurations are also compatible with certain embodiments described herein. For example, the thermoelectric assembly 202 of FIG. 13 can be used with a first working fluid that comprises a liquid, a gas, or a combination of a liquid and a gas, and a second working fluid that comprises a liquid, a gas, or a combination of a liquid and a gas. Furthermore, in other examples, the thermoelectric assembly 202 can be used with one or more of the hot side or the cold side in thermal communication with a solid surface rather than a liquid or a gas.

The at least one first heat exchanger 210 can comprise a first fluid conduit 212 (e.g., through which a high temperature gas can flow) comprising a thermally conductive material (e.g., copper). For example, as shown in FIGS. 13, 14A, and 14B, the first fluid conduit 212 can have a polygonal (e.g., hexagonal) cross-sectional shape with a plurality of flat surfaces configured to be mechanically coupled to the plurality of thermoelectric elements 232. The first fluid conduit 212 can further comprise an inner region configured to contain the first working fluid. For example, as shown in FIGS. 13, 14A, and 14B, the first fluid conduit 212 can comprise an inner region with a plurality of fins 214 in thermal communication with the first working fluid. The at least one first heat exchanger 210 (e.g., the fins 214) can comprise a plurality of second mechanically compliant elements 216 (e.g., flexible folds or flexible bellows) that are positioned and spaced apart from one another (e.g., sandwiched between adjacent sections of the at least one first heat exchanger 210) along an axial direction of the first fluid conduit 212. These second mechanically compliant elements 216 can be configured to flex in response to thermal expansion or contraction in the axial direction. Depending on usage, the first fluid conduit 212, the fins 214 and the second mechanically compliant elements 216 can comprise various shapes or materials.

The at least one second heat exchanger 220 can comprise a plurality of second fluid conduits 222 (e.g., through which a low temperature fluid can flow) substantially surrounding the at least one first heat exchanger 210. For example, as shown in FIG. 13, the at least one second heat exchanger 220 comprises six second fluid conduits 222, with each second fluid conduit 222 comprising a flat surface configured to be mechanically coupled to the plurality of thermoelectric elements 232. Each second fluid conduit 222 can further comprise an inner region configured to contain the second working fluid. The second fluid conduits 222 can be positioned along an outer perimeter of the at least one second heat exchanger 220. Depending on usage, one or more of the second fluid conduits 222 can comprise fins and can comprise tubes of various shapes or materials. The at least one second heat exchanger 220 can comprise sections formed by extrusion. FIG. 13 shows one such section.

The at least one second heat exchanger 220 can further comprise the at least one mechanically compliant element 240. For example, as shown in FIG. 13, the at least one second heat exchanger 220 can comprise a plurality of mechanically compliant elements 240, with each mechanically compliant element 240 mechanically coupled to a pair of adjacent second fluid conduits 222 of the plurality of second fluid conduits 222. The mechanically compliant elements 240 can each comprise a flexible portion of the at least one second heat exchanger 220. For example, as shown in FIG. 13, the mechanically compliant elements 240 each comprise a curved portion or an angled portion of the at least one second heat exchanger 220 that is configured to flex (e.g., change its radius of curvature or its opening angle) in response to thermal expansion or contraction of the at least one thermoelectric assembly 230.

In certain embodiments, the plurality of thermoelectric elements 232 are sandwiched between the first fluid conduit 212 of the at least one first heat exchanger 210 and the plurality of second fluid conduits 222 of the at least one second heat exchanger 220. For example, as shown in FIGS. 13 and 14B, the plurality of thermoelectric elements 232 comprise sets 232a, 232b, . . . of thermoelectric elements 232, with each set of thermoelectric elements 232 sandwiched between and in thermal communication with the flat surface of a corresponding second fluid conduit 222 and a corresponding flat surface of the first fluid conduit 212.

The sets of thermoelectric elements 232 can comprise a plurality of p-type thermoelectric elements and a plurality of n-type thermoelectric elements. In the example structure of FIG. 14A, a first set 232a of thermoelectric elements 232 comprises three p-type thermoelectric elements and a second set 232b of thermoelectric elements 232 comprises three n-type thermoelectric elements. The first set 232a and the second set 232b are each mechanically coupled (e.g., fixed or bonded) to a flat surface (e.g., comprising copper) of a first section 210a of the first heat exchanger 210.

In the example structure of FIG. 14B, the first and second sections 210a, 210b of the first heat exchanger 210 are adjacent to one another, and the second heat exchanger 220 comprises a plurality of sections (e.g., a first section 220a and a second section 220b adjacent to the first section 220a). The first section 220a of the second heat exchanger 220 can be mechanically coupled (e.g., contacting or floating) to the second set 232b (e.g., n-type) of thermoelectric elements 232 mechanically coupled (e.g., fixed or bonded) to the first section 210a of the first heat exchanger 210. The first section 220a of the second heat exchanger 220 can also be mechanically coupled (e.g., contacting or floating) to the first set 232a (e.g., p-type) of thermoelectric elements 232 mechanically coupled (e.g., fixed or bonded) to the second section 210b of the first heat exchanger 210. The second section 220b of the second heat exchanger 220 similarly spans across portions of two underlying sections of the first heat exchanger 210 and is mechanically coupled to a first set 232a and a second set 232b of thermoelectric elements 232. In this way, the sections of the first heat exchanger 210 and the sections of the second heat exchanger 220 are positioned offset from one another.

In certain such embodiments in which the thermoelectric elements 232 are in electrical communication with corresponding sections of the first heat exchanger 210 and the second heat exchanger 220, the thermoelectric elements 232 are in a “stonehenge” configuration with electrical current flowing generally in the axial direction through the first heat exchanger 210 and the second heat exchanger 220 (see, FIG. 14B in which the electrical current is shown by a series of arrows). In this way, the first heat exchanger 210 can serve as a first electrically conductive shunt connecting the thermoelectric elements 232 with one another (e.g., electrical current flows through the first section 210a of the first heat exchanger 210 from the first set of thermoelectric elements 232a to the second set of thermoelectric elements 232b mounted to the first section 210a of the first heat exchanger 210), and the second heat exchanger 220 can serve as a second electrically conductive shunt connecting the thermoelectric elements 232 with one another (e.g., electrical current flows through a first section 220a of the second heat exchanger 220 from second set of thermoelectric elements 232b mounted to the first section 210a of the first heat exchanger 210 to a first set of thermoelectric elements 232a mounted to an adjacent second section 210b of the first heat exchanger 210). Alternatively, in certain other embodiments, the electrical current can flow through other structures (e.g., the second mechanically compliant elements 216 between the adjacent sections 210a, 210b; electrical jumpers electrically coupling adjacent sections of the second heat exchanger 220).

In certain embodiments in which the second heat exchanger 220 comprises a plurality of sections 220a, 220b, . . . , the second heat exchanger 220 can further comprise a plurality of third mechanically compliant elements sandwiched between adjacent sections of the second heat exchanger 220 and configured to flex in response to thermal expansion or contraction in the axial direction. For example, the third mechanically compliant element can comprise a sealing link (e.g., vulcanized rubber) between adjacent sections of the second heat exchanger 220 (not shown in FIG. 14B).

The thermoelectric elements 232 can be sealed within an environment comprising a gas. An enclosure 236 can be formed by the at least one first heat exchanger 210 (e.g., comprising a gas-impermeable barrier) and the at least one second heat exchanger 220 (e.g., comprising a gas-impermeable barrier), with the enclosure 236 containing the plurality of thermoelectric elements 232 containing an atmosphere that is substantially inert to the thermoelectric elements 232 (e.g., an inert gas, such as a noble gas or nitrogen). For example, the enclosure 236 can be formed by a plurality of adjacent sections 210a, 210b, of the at least one first heat exchanger 210, the second mechanically compliant elements 216 between the adjacent sections 210a, 210b, . . . , a plurality of adjacent sections 220a, 220b, of the at least one second heat exchanger 220 (including the mechanically compliant elements 240), and the third mechanically compliant elements between the adjacent sections 220a, 220b, ..., along with end structures (e.g., one or more caps, not shown) that complete the enclosure 236. A plurality of thermoelectric assemblies 202, along with the end structures, can be considered to form a thermoelectric module in which the thermoelectric elements 232 are encapsulated.

In certain embodiments, the thermoelectric elements 232 are bonded (e.g., brazed or soldered) to the at least one first heat exchanger 210 (e.g., to the flat outer surfaces forming a hexagon) and are slidably contacting the at least one second heat exchanger 220 (e.g., with a layer of thermally conductive grease between surfaces of the thermoelectric elements 232 and the at least one second heat exchanger 220). The bonds of the at least one first heat exchanger 210 to the thermoelectric elements 232 can provide electrical communication and thermal communication between the at least one first heat exchanger 210 to the thermoelectric elements 232. The sliding contact of the at least one second heat exchanger 220 to the thermoelectric elements 232 can provide electrical communication and thermal communication between the at least one second heat exchanger 220 to the thermoelectric elements 232. Radial thermal expansion (e.g., radial thermal expansion of the at least one first heat exchanger 210 or the thermoelectric elements 232) can compress the thermoelectric elements 232 against the at least one second heat exchanger 220, thereby improving the thermal conductivity across the interface, but also creating stress on the thermoelectric elements 232.

The at least one mechanically compliant element 240 of the at least one second heat exchanger 220 can be configured to allow such radial thermal expansion to occur while controlling the amount of stress experienced by the thermoelectric elements 232. For example, the mechanically compliant elements 240 of FIG. 13 each comprise a curved portion of the at least one second heat exchanger 220 that is configured to flex (e.g., increase its radius of curvature) upon radial thermal expansion of the at least one first heat exchanger 210, the thermoelectric elements 232, or both. Alternatively, the mechanically compliant elements 240 can each comprise an angled portion of the at least one second heat exchanger 220 that is configured to flex (e.g., increase its opening angle) upon radial thermal expansion of the at least one first heat exchanger 210, the thermoelectric elements 232, or both. In these structures, the at least one second heat exchanger 220 can increase its radial dimension to accommodate the thermal expansion of the structures encircled by the at least one second heat exchanger 220 and to reduce the amount of stress experienced by the thermoelectric elements 232.

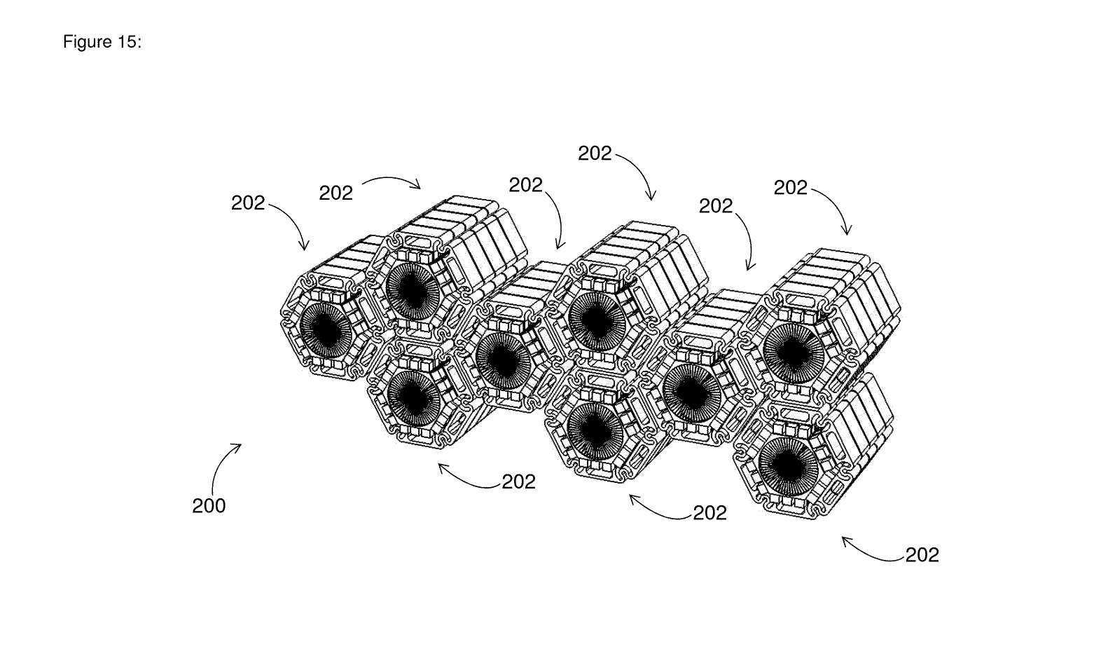

FIG. 15 schematically illustrates an example array of thermoelectric systems 200 each comprising a plurality of thermoelectric assemblies 202 in accordance with certain embodiments described herein. The thermoelectric assemblies 202 are hexagonally-shaped and are arranged in groups each of which comprises multiple thermoelectric assemblies 202 that are generally aligned with one another to form a common first fluid conduit 212 and a common plurality of second fluid conduits 222 (e.g., a thermoelectric system 200 as schematically illustrated by FIG. 14B). Each group forms a cylindrical structure with a hexagonal cross-section. As shown in FIG. 15, these groups of thermoelectric assemblies 202 can be arranged to form the array with the first fluid conduits 212 generally parallel to one another and the second fluid conduits 222 generally parallel to one another. Groups can be placed adjacent to one another in a honeycomb pattern (e.g., to provide a space-filling structure). The number of thermoelectric elements per thermoelectric assembly, the number of thermoelectric assemblies per group, the number of groups per thermoelectric system, and the arrangement of the groups can be selected based on the desired usage, power output, or voltage.

Discussion of the various configurations herein has generally followed the configurations schematically illustrated in the figures. However, it is contemplated that the particular features, structures, or characteristics of any configurations discussed herein may be combined in any suitable manner in one or more separate configurations not expressly illustrated or described. In many cases, structures that are described or illustrated as unitary or contiguous can be separated while still performing the function(s) of the unitary structure. In many instances, structures that are described or illustrated as separate can be joined or combined while still performing the function(s) of the separated structures.

Various configurations have been described above. Although the invention has been described with reference to these specific configurations, the descriptions are intended to be illustrative and are not intended to be limiting. Various modifications and applications may occur to those skilled in the art without departing from the true spirit and scope of the invention as defined in the appended claims.

What is claimed is:

1. A thermoelectric system comprising:
at least one first heat exchanger configured to be in thermal communication with a heat source;
at least one second heat exchanger configured to be in thermal communication with a heat sink; and
at least one thermoelectric assembly comprising a plurality of thermoelectric elements sealed within an environment comprising a gas, the at least one thermoelectric assembly mechanically coupled to the at least one first heat exchanger and mechanically coupled to the at least one second heat exchanger, the at least one thermoelectric assembly sandwiched between the at least one first heat exchanger and the at least one second heat exchanger, wherein the at least one second heat exchanger comprises at least one mechanically compliant element configured to flex in response to at least one dimensional change of the at least one thermoelectric assembly due to thermal expansion or contraction.

2. The thermoelectric system of claim 1, wherein the at least one mechanically compliant element is further configured to reduce a shear load on the plurality of thermoelectric elements.

3. The thermoelectric system of claim 1, wherein the at least one dimensional change comprises elongation of at least some thermoelectric elements of the plurality of thermoelectric elements.

4. The thermoelectric system of claim 1, wherein the at least one mechanically compliant element comprises at least one membrane, at least a portion of the at least one membrane configured to flex in response to the at least one dimensional change of the at least one thermoelectric assembly.

5. The thermoelectric system of claim 4, wherein the portion of the at least one membrane is configured to stretch in a direction perpendicular to a direction of heat flow from the at least one first heat exchanger to the at least one second heat exchanger.

6. The thermoelectric system of claim 4, wherein the heat source comprises a first working fluid and the heat sink comprises a second working fluid, wherein the at least one membrane is in contact with the second working fluid.

7. The thermoelectric system of claim 5, wherein the at least one membrane comprises a gas-impermeable barrier between the environment and the second working fluid.

8. The thermoelectric system of claim 4, wherein the at least one membrane comprises elastic polymers.

9. The thermoelectric system of claim 4, wherein the at least one membrane comprises a first metal layer, a second metal layer, and a dielectric layer between the first metal layer and the second metal layer.

10. The thermoelectric system of claim 9, wherein at least one of the first metal layer and the second metal layer comprises copper, aluminum, nickel, or an alloy of one or more of copper, aluminum, and nickel.

11. The thermoelectric system of claim 4, wherein the at least one membrane comprises regions between at least some adjacent thermoelectric elements of the plurality of thermoelectric elements, the regions configured to flex in response to the at least one dimensional change of the at least one thermoelectric assembly.

12. The thermoelectric system of claim 4, wherein the at least one membrane comprises a plurality of electrically conductive shunts providing electrical communication among at least some of the thermoelectric elements of the plurality of thermoelectric elements.

13. The thermoelectric system of claim 4, further comprising a plurality of springs mechanically coupled to the at least one membrane and configured to apply a restoring force to the at least one membrane in response to the at least one dimensional change of the at least one thermoelectric assembly.

14. The thermoelectric system of claim 13, wherein the plurality of springs apply a compressive force to the plurality of thermoelectric elements.

15. The thermoelectric system of claim 13, wherein the plurality of springs comprises a plurality of fins of the at least one second heat exchanger.

16. The thermoelectric system of claim 4, wherein the at least one first heat exchanger comprises silicon carbide or aluminum silicon carbide.

17. The thermoelectric system of claim 16, wherein the at least one first heat exchanger comprises a plurality of electrically conductive shunts providing electrical communication among at least some of the thermoelectric elements of the plurality of thermoelectric elements.

18. The thermoelectric system of claim 4, wherein the at least one thermoelectric assembly comprises a plurality of thermoelectric assemblies, the at least one membrane comprises a plurality of membranes, and the at least one second heat exchanger further comprises a fluid conduit comprising the plurality of membranes, each membrane of the plurality of membranes in thermal communication with a corresponding thermoelectric assembly of the plurality of thermoelectric assemblies, wherein the heat source comprises a first working fluid and the heat sink comprises a second working fluid, wherein the second working fluid flowing through the fluid conduit is in thermal communication with each membrane of the plurality of membranes sequentially.

19. The thermoelectric system of claim 4, further comprising a bypass region configured to thermally insulate the at least one first heat exchanger from a surrounding environment, the heat source comprising a first working fluid and the heat sink comprises a second working fluid, the thermoelectric system configured to selectively allow at least a portion of the first working fluid to flow through the bypass region upon a temperature of the first working fluid exceeding a predetermined temperature.

20. The thermoelectric system of claim 1, wherein the at least one first heat exchanger comprises a first fluid conduit and the at least one second heat exchanger comprises a plurality of second fluid conduits substantially surrounding the at least one first heat exchanger, the plurality of thermoelectric elements sandwiched between the first fluid conduit and the plurality of second fluid conduits, wherein each mechanically compliant element of the at least one mechanically compliant element is mechanically coupled to a pair of adjacent second fluid conduits of the plurality of second fluid conduits.

21. The thermoelectric system of claim 20, wherein each second fluid conduit of the plurality of second fluid conduits comprises a flat surface, the first fluid conduit comprises a plurality of flat surfaces, and the plurality of thermoelectric elements comprising sets of thermoelectric elements, wherein each set of thermoelectric elements of the plurality of thermoelectric elements is sandwiched between and in thermal communication with the flat surface of a corresponding second fluid conduit and a corresponding flat surface of the first fluid conduit.

22. The thermoelectric system of claim 21, wherein the first fluid conduit has a polygonal cross-sectional shape.

23. The thermoelectric system of claim 21, wherein the at least one second heat exchanger is configured to expand in a radial direction relative to the first fluid conduit by flexing the at least one mechanically compliant element in response to thermal expansion of the plurality of thermoelectric elements.

24. The thermoelectric system of claim 20, wherein the plurality of thermoelectric elements are sealed within an environment comprising a gas, and the at least one first heat exchanger comprises a gas-impermeable barrier enclosing the gas.

25. The thermoelectric system of claim 20, wherein the heat source comprises a first working fluid and the heat sink comprises a second working fluid, wherein the first fluid conduit comprises a plurality of fins in thermal communication with the first working fluid.

26. The thermoelectric system of claim 25, wherein the plurality of fins comprise a plurality of second mechanically compliant elements positioned and spaced apart from one another along an axial direction of the first fluid conduit, the plurality of second mechanically compliant elements configured to flex in response to thermal expansion or contraction of the plurality of fins in the axial direction.

27. A method of fabricating a thermoelectric system, the method comprising:
mechanically coupling at least one first heat exchanger to a plurality of thermoelectric elements, the at least one first heat exchanger configured to be in thermal communication with a heat source;
mechanically coupling at least one second heat exchanger to the plurality of thermoelectric elements, the at least one second heat exchanger configured to be in thermal communication with a heat sink, wherein the plurality of thermoelectric elements is sandwiched between the at least one first heat exchanger and the at least one second heat exchanger, wherein the at least one second heat exchanger comprises at least one mechanically compliant element configured to flex in response to at least one dimensional change of the thermoelectric system due to thermal expansion or contraction; and
sealing the plurality of thermoelectric elements within an environment comprising a gas.

28. The method of claim 27, wherein the at least one mechanically compliant element comprises a gas-impermeable barrier and sealing the plurality of thermoelectric elements within the environment comprises using the at least one mechanically compliant element to confine the gas within the environment.

29. The method of claim 27, wherein the at least one mechanically compliant element comprises at least one membrane, at least a portion of the at least one membrane configured to flex in response to the at least one dimensional change of the at least one first heat exchanger, the plurality of thermoelectric elements, or both.

30. The method of claim 27, wherein the at least one first heat exchanger comprises a first fluid conduit and the at least one second heat exchanger comprises a plurality of second fluid conduits substantially surrounding the at least one first heat exchanger, the plurality of thermoelectric elements sandwiched between the first fluid conduit and the plurality of second fluid conduits, wherein each mechanically compliant element of the at least one mechanically compliant element is mechanically coupled to a pair of adjacent second fluid conduits of the plurality of second fluid conduits.
